(19) United States
(12) Patent Application Publication
(10) Pub. No.: US 2026/0050227 A1
(43) Pub. Date: Feb. 19, 2026

(54) ON TOOL METROLOGY SCHEME FOR ADVANCED PACKAGING

(71) Applicant: Applied Materials, Inc., Santa Clara, CA (US)

(72) Inventor: Ulrich MUELLER, Berkeley, CA (US)

(21) Appl. No.: 19/101,094

(22) PCT Filed: Sep. 11, 2023
(86) PCT No.: PCT/US2023/032382

§ 371 Date: Feb. 4, 2025

Related U.S. Application Data
(60) Provisional application No. 63/408,418, filed on Sep. 20, 2022.

(51) Int. Cl. G03F 9/00; G01B 11/27; G02B 21/12; G02B 21/24; G03F 7/00

(52) U.S. Cl. CPC G03F 9/7088; G01B 11/272; G02B 21/12; G02B 21/241; G03F 7/70633; G03F 7/70655; G03F 7/706845; G03F 7/706847; G03F 7/706849; G03F 7/706851; G03F 7/70716; G03F 9/7019; G03F 9/7053; G03F 9/7065; G03F 9/7069; G03F 9/7092; G03F 9/7096

(57) ABSTRACT

Systems and methods disclosed herein relate to a digital lithography system and method for alignment resolution with the digital lithography system. The digital lithography system includes a metrology system configured to improve overlay alignment for different layers of the lithography process. The metrology system allows for decreased size of alignment marks. Based on determining the positions of alignment marks with the metrology system, correction data is obtained to achieve accurate overlay of layers on subsequent patterning processes.

### BACKGROUND

### Field

Embodiments of the present disclosure generally relate to a digital lithography system and method for alignment resolution with the digital lithography system.

### Description of the Related Art

Maskless lithography is used in the manufacturing of semiconductor devices, such as for back-end processing of semiconductor devices, and display devices, such as liquid crystal displays (LCDs). It is desirable to align subsequent layers of a mask pattern into a photoresist disposed over a substrate. It is also desirable to position dies on the substrate accurately. Accordingly, what is needed in the art is an improved system and method for improving overlay accuracy and digital correction of digital lithography processes.

### SUMMARY

In one embodiment, a metrology system is provided. The metrology system includes a microscope body, a lens coupled to the microscope body, and a focusing stage disposed between the microscope body and the lens. The focusing stage is configured to move the lens to adjust a focus of the lens. The metrology system further includes a camera coupled to the microscope body, a first LED, a second LED, and a third LED coupled to the microscope body. The LEDs deliver light to the microscope body. The metrology system further includes an illuminator disposed below the lens.

In another embodiment, a digital lithography system is provided. The digital lithography system includes a slab, a moveable stage disposable over the slab and the stage configured to support a substrate. The digital lithography system further includes a support coupled to the slab having an opening to allow the moveable stage to pass thereunder, one or more image projection systems (IPSs) coupled to the support and one or more metrology systems coupled to the support. The one or more metrology systems each include a microscope body, a lens coupled to the microscope body, and a focusing stage disposed between the microscope body and the lens. The focusing stage is configured to move the lens to adjust a focus of the lens. The metrology system further includes a camera coupled to the microscope body, a first LED, a second LED, and a third LED coupled to the microscope body. The LEDs deliver light to the microscope body. The metrology system further includes an illuminator disposed below the lens.

In yet another embodiment, a method of mark measurements on a substrate is provided. The method includes capturing images of alignment marks on a substrate or die marks on dies of the substrate positioned on a digital lithography system. The alignment marks and the die marks each have a width less than 50 um, wherein the images of the alignment marks or the die marks are captured with a microscope body with an objective lens. The method further includes determining a position of the alignment marks and the die marks, comparing the position of the alignment marks and the die marks with a design file to obtain correction data; and patterning subsequent layers onto the substrate with reference to the correction data. The correction data improves overlay alignment accuracy of the subsequent layers and corrects die placement errors on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a perspective view of a digital lithography system according to embodiments described herein.

FIG. 2 is a schematic, top view of a substrate, according to embodiments described herein.

FIG. 3 is a schematic diagram of a metrology system, according to embodiments described herein

FIG. 4 is a flow diagram of a method for alignment resolution with the digital lithography system, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to a digital lithography system and method for alignment resolution with the digital lithography system. The digital lithography system includes a metrology system configured to improve overlay alignment for different layers of the lithography process. The metrology tool is integrated with the lithography system. The metrology system is configured to align the substrate to the digital lithography system. The metrology system is also configured to facilitate measurement of package, die, and alignment marks for in situ verification of process stability and die placement data for digital data correction. In operation, the metrology system transfers data to the local camera system of the lithography system allowing the local camera system to align and digitally correct any die placement errors. As such, the metrology system integrated with the digital lithography system allows for improved layer overlay alignment with the digital lithography tool for small alignment marks in advanced packages. Additionally, measurement of the die positions in the packages for digital correction with the metrology system increases yield and enables higher 2D and 3D package integration.

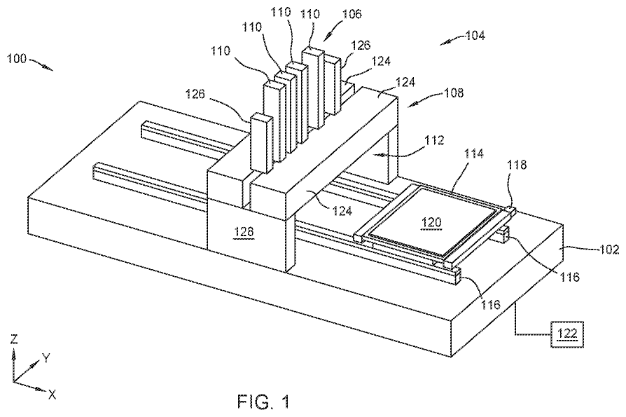

FIG. 1 is a perspective view of a digital lithography system 100, according to embodiments described herein. The digital lithography system 100 includes a stage 114 and a processing apparatus 104. The stage 114 is supported by a pair of tracks 116 disposed on a slab 102. A substrate 120 is supported by the stage 114. The stage 114 moves along the pair of tracks 116 in the X direction as indicated by the coordinate system shown in FIG. 1. The stage 114 also moves in the Y-direction for processing and/or indexing a substrate 120. The stage 114 is capable of independent operation and can scan the substrate 120 in one direction and step in the other direction. An encoder 118 is coupled to the stage 114 in order to provide information of the location of the stage 114 to a controller 122.

The controller 122 is generally designed to facilitate the control and automation of the processing techniques described herein. The controller 122 may be coupled to or in communication with the processing apparatus 104, the stage 114, and the encoder 118. The processing apparatus 104 and the encoder 118 may provide information to the controller 122 regarding the substrate processing and the substrate aligning. For example, the processing apparatus 104 may provide information to the controller 122 to alert the controller 122 that substrate processing has been completed. A program (or computer instructions), which may be referred to as an imaging program, readable by the controller 122, determines which tasks are performable on a substrate. The program includes a design file and code to monitor and control the processing time and substrate position. The design corresponds to a pattern to be written into the photoresist using the electromagnetic radiation. The controller 122 includes a central processing unit (CPU) configured to process computer-executable instructions, e.g., stored in a memory or storage, and to cause the controller to perform embodiments of methods described herein. The memory in the controller 122 may include components configured to run programs and software to perform embodiments of the methods described herein.

The substrate 120 comprises any suitable material, for example, glass, which is used as part of a flat panel display. The substrate 120 has a film layer to be patterned formed thereon, such as by pattern etching thereof, and a photoresist layer formed on the film layer to be patterned, which is sensitive to electromagnetic radiation, for example UV or deep UV “light”. A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. After exposure of the photoresist to the electromagnetic radiation, the resist is developed to leave a patterned photoresist on the underlying film layer. Then, using the patterned photoresist, the underlying thin film is pattern etched through the openings in the photoresist to form a portion of the electronic circuitry of the display panel.

The processing apparatus 104 includes a support 108 and a processing unit 106. The support 108 includes a pair of risers 128, disposed on the slab 102, supporting two or more bridges 124. The pair of risers 128 and bridges 124 form an opening 112 for the pair of tracks 116 and the one or more stages 114 to pass under the processing unit 106. The processing unit 106 is supported by the support 108. The processing unit 106 includes a plurality of image projection systems (IPSs) 110 and one or more metrology systems 126. The plurality of IPSs 110 and the metrology systems 126 are supported by one or more bridges 124. Although FIG. 1 depicts four IPSs and two metrology systems 126, the processing unit 106 is not limited in how the metrology systems 126 and the IPSs 110 are positioned on the support 108. In one example, the number of IPSs 110 is equal to the number of metrology systems 126. In another example, the number of IPSs 110 is less than the number of metrology systems 126. In yet another example, the number of IPSs is more than the number of metrology systems 126. The metrology systems 126 may be positioned as needed relative to the IPSs 110. For example, the metrology system 126 may be positioned between two IPSs 110. The metrology system 126 and the IPSs 110 are positioned on the support 108 to be above the substrate 120. As such, the metrology system 126 and the IPSs have a field of view that includes the substrate 120, when the substrate 120 is positioned under the support 108.

In one embodiment, which can be combined with other embodiments described herein, the processing unit 106 contains as many as 84 IPS's 110. Each IPS 110 includes a spatial light modulator. The spatial light modulator includes, but is not limited to, microLEDs, OLEDs, digital micromirror devices (DMDs), liquid crystal displays (LCDs), and vertical-cavity surface-emitting lasers (VCSELs). The components of each of the IPS 110 vary depending on the spatial light modulator being used.

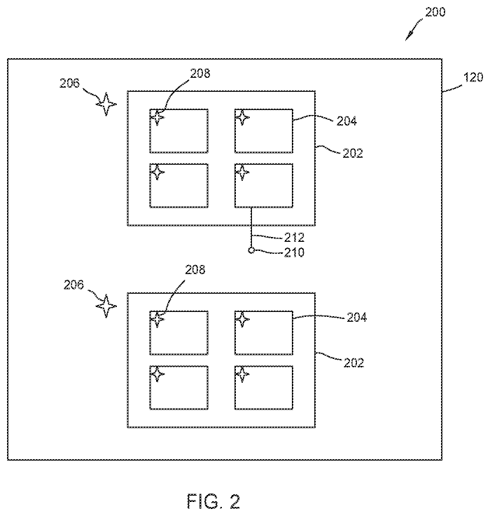

FIG. 2 is a schematic, top view of a substrate 120, according to embodiments described herein. The substrate 120 includes a substrate layout design 200, according to certain embodiments. In this context, a layout design may be a layout of design elements to be patterned on the substrate 120, developed by a designer, programmatically, or a combination of both. A layout design may include more than one layer, for patterning on the substrate 120. Multiple layers may be patterned to form computer processing units, graphics processing units, and the like. Substrate layout design 200 is provided to the digital lithography system 100 for patterning on the substrate 120, and includes a variety of features, limited only by the design required to meet one or more customer requirements. Such features may include connection lines, logic, transistors, and vias from other layers. The features may have a design connection point 210 and according to certain embodiments may be positioned to be connected via pixel model 212 to another design connection point on the substrate 120, or to a package 202. Although shown as a points, design connection point 210 may include both a point, and a line extending from the point.

The substrate 120 includes one or more packages 202 formed on the substrate 120. Each package 202 includes collections of one or more dies 204. The number of packages 202 is not limited by FIG. 2. The number of dies 204 is not limited by FIG. 2. The dies 204 may be a pre-assembled/fabricated elements that may be placed on substrate 120 during manufacturing and in some embodiments may be fabricated separately on substrate 120. According to certain embodiments, the dies 204 may include functional elements that provide functionality as part of the substrate layout design 200, and may include functional elements such as memories, processors, application specific logic, lens arrays, active quantum dots, color filters, light focusing sidewall mirrors, and other components for additional functionality.

The substrate 120 includes one or more alignment marks 206. The alignment marks 206 are patterned by one or more IPSs 110, and positioned to be measured by one or more IPSs and the metrology systems 126. The alignment marks 206 have known positions in the co-ordinate system of stage 114, to which substrate 120 is attached. Collecting data of the positions of the alignment marks 206 enables alignment resolution. For example, overlay alignment between multiple layers is achieved via the alignment marks 206.

Additionally, each die 204 may include a die mark 208. In some embodiments, which can be combined with other embodiments described herein, the die marks 208 are on the packages 202. The die marks 208 are patterned by one or more IPSs 110, and positioned to be measured by one or more IPSs and the metrology systems 126. The die marks 208 have known positions in a lithography coordinate system of stage 140, to which substrate 120 is attached. The die marks 208 are utilized to indicate placement for digital correction printing. For example, shifting of the dies 204 and rotation of the dies 204 can be addressed with positon data of the die marks 208.

The alignment marks 206 and the die marks 208 have a width of less than about 50 μm. The metrology systems 126 are configured to measure the alignment marks 206 and the die marks 208 despite the smaller width. Although the alignment marks 206 and the die marks 208 have a star shape in FIG. 2, the alignment marks 206 and the die marks 208 are not limited in shape. For example, the alignment marks 206 and the die marks 208 may have a circular, square, rectangular, cross, triangular, or any other suitable shape. As the width of alignment marks decrease in size, the metrology systems 126 allow for imaging of the alignment marks 206 and the die marks 208.

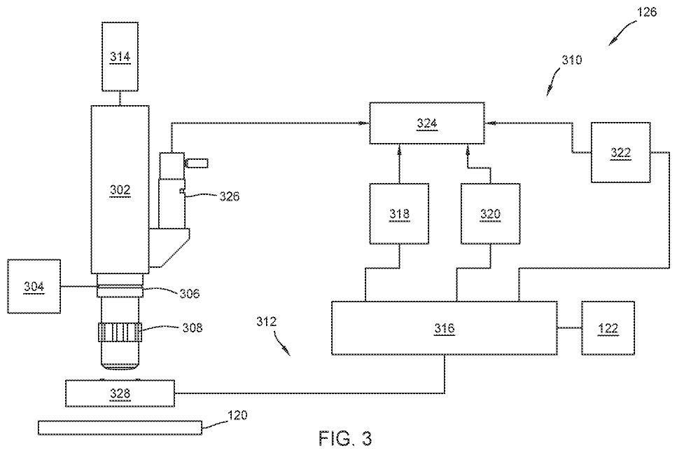

FIG. 3 is a schematic diagram of a metrology system 126, according to embodiments described herein. The metrology system 126 is positioned on the support 108 in order to capture images and measurement data on the substrate 120. The metrology system 126 is electrically connected to the controller 122. The controller 122 is generally designed to facilitate the control and automation of the processing techniques described herein. For example, the controller 122 provides instructions to the metrology system 126 to capture images. The controller 122 also receives and sends data acquired by the metrology system 126. The metrology system 126 also adjusts focus, as instructed by the controller 122. The controller 122 further enables the metrology system to communicate with the IPSs 110 and share date therebetween. For example, positon data can be shared between the IPSs 110 and the metrology system 126 to improve alignment resolution. The metrology system 126 includes a microscope body 302, a piezoelectric motor 304, a focusing stage 306, an objective lens 308, bright field illumination system 310, a dark field illumination system 312, and a camera 314. The microscope body 302 includes an input arm 326. The input arm 326 is coupled to the bright field illumination system 310. The microscope body 302 is positioned towards the substrate 120 sitting on the stage 114 (see FIG. 1).

The camera 314 is electrically connected to the microscope body 302. The camera 314 captures images of the substrate 120. The images are provided to the controller 122. The camera 314 captures images at multiple different focuses. The objective lens 308 is coupled to a focusing stage 306. The objective lens 308 is the optical element that gathers light from the object being observed and focuses the light rays to produce a real image. The objective lens 308 includes a magnification that ranges between about 4 times and about 100 times the object being observed.

The focusing stage 306 is disposed between the microscope body 302 and the objective lens 308. The focusing stage 306 is configured to move in a vertical direction (defined as normal to the surface of the substrate 120 to be measured) such that the objective lens 308 also moves in a substantially vertical direction. The focusing stage 306 is coupled to the piezoelectric motor 304. The piezoelectric motor 304 provides power to the focusing stage 306 to move the objective lens 308. The controller 122 instructs the piezoelectric motor 304 when to provide power to the focusing stage 306. In operation, the objective lens 308 moves in a substantially vertical direction to capture images of the substrate 120. The focus of the objective lens changes depending on the vertical position. The camera 314 captures images of the substrate 120 at each vertical position with a different focus.

The bright field illumination system 310 includes an illumination controller 316, a first LED 318, a second LED 320, a third LED 322, and a light delivery module 324. The bright field illumination yields dark objects on a bright background, where the bright background is created with the LEDs. The bright field illumination system 310 provides bright field light to the input arm 326. The bright field light from the LEDs (first LED 318, second LED 320, and the third LED 322) is directed through the microscope body 302 to illuminate the substrate 120. The first LED 318, the second LED 320, and the third LED 322 are connected to the light delivery module 324. The light delivery module 324 includes one or more dichroic mirrors therein to deliver light from the one or more of the first LED 318, the second LED 320, and the third LED 322 to the input arm 326. The bright field light may be delivered to the input arm 326 from the light delivery module 324 via a coaxial fiber cable. Each of the first LED 318, the second LED 320, and the third LED 322 are configured to provide a bright field light at different wavelengths. For example, the first LED 318 provides light at a wavelength between about 470 nm to about 530 nm, the second LED 320 provides light at a wavelength between about 365 nm and about 590 nm, and the third LED 322 provides light at a wavelength between about 617 nm and about 850 nm. In some embodiments, light from the LEDs can be combined in the light delivery module 324 to adjust the wavelength of the light delivered to the input arm 326. As different substrates behave differently, providing different wavelengths to the substrates improves visibility of the substrates to be measured. The illumination controller 316, in communication with the controller 122, instructs the first LED 318, the second LED 320, and the third LED 322 to provide light to the input arm 326 to improve visibility of the substrate 120. Therefore, the bright field illumination system 310 is configured to provide multi-color illumination to the substrate 120, and is controlled by the illumination controller 316.

The dark field illumination system 312 includes a dark field illuminator 328 and the illumination controller 316. The dark field illuminator 328 is a light ring with a plurality of LEDs disposed thereon. The dark field illumination system 312 is positioned between the objective lens 308 and the substrate 120. In some embodiments, which can be combined with other embodiments described herein, the LEDs are positioned at an angle relative to the surface of the substrate 120 to be measured. The illuminator controller 316 is electrically connected to the dark field illuminator 328. The illumination controller 316, in communication with the controller 122, instructs the dark field illuminator 328 to provide light to improve visibility of the substrate 120. The dark field illumination yields a dark background around the substrate 120 to improve visibility and to highlight any surface defects.

In operation, the metrology system 126 is positioned above a substrate 120 to be measured. The dark field illumination system 312 and the bright field illumination system 310 illuminate the substrate 120. The objective lens 308 is moved in a substantially vertical direction by the focusing stage 306 while the camera 314 captures images at each different focus. The images are provided to the controller 122 for facilitation.

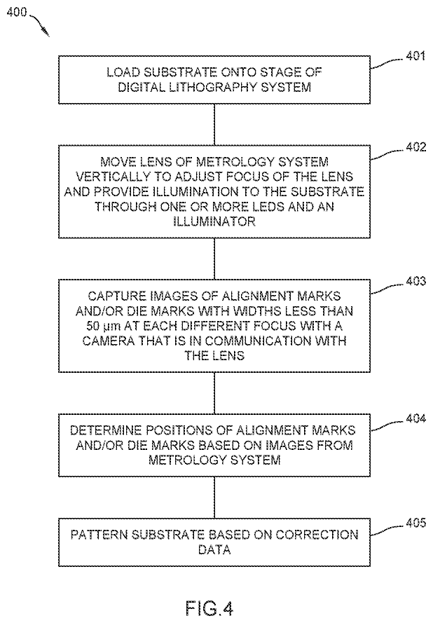

FIG. 4 is a flow diagram of a method 400 for alignment resolution with the digital lithography system 100. The method 400 utilizes one or more metrology systems 126 to allow for increased measurement of alignment marks and die marks with widths less than 50 μm. To facilitate explanation, the method 400 is described with reference to FIGS. 1-3. The metrology tool improves process stability because the metrology tool can be combined with offline tools for statistical process control. The method 400 determines correction data to provide overlay alignment accuracy and digital die correction during subsequent patterning processes. The correction data will improve yield of semiconductor devices due to less variance from a design file.

At operation 401, a substrate 120 is loaded onto a stage 114 of a digital lithography system 100. The substrate 120 includes one or more packages 202 which each include one or more dies 204. The substrate 120 includes alignment marks 206 on the substrate 120 and die marks 208 on the dies 204. The alignment marks 206 are disposed on the substrate 120 to establish a general coordinate system of the entire substrate 120. The die marks 208 are disposed on the dies 204 to establish where the dies 204 are positioned on the substrate 120. For example, the die marks 208 are utilized to determine shifting and rotation of the dies 204 relative to the alignment marks 206. Further, the die marks 208 are utilized for digital die correction. Digital die correction allows for correction of the placement of connection points 210 and pixel models 212 in subsequent layers patterned on the substrate 120. The stage 114 is positioned under one or more IPSs 110 and the one or more metrology systems 126.

At operation 402, the objective lens 308 is moved in a substantially vertical direction by the focusing stage 306 and the bright field illumination system 310 provides bright field light to the input arm 326. The objective lens 308 is moved substantially vertically via the focusing stage 306 to adjust the focus of the objective lens 308. The bright field light from the LEDs (first LED 318, second LED 320, and the third LED 322) is directed through the microscope body 302 to illuminate the substrate 120. The illumination controller 316, in communication with the controller 122, instructs the dark field illuminator 328 to provide light to improve visibility of the substrate 120. The dark field illumination yields a dark background around the substrate 120 to improve visibility and to highlight any surface defects.

At operation 403, the metrology systems 126 capture multiple images of one or both of the alignment marks 206 and the die marks 208. The camera 314, which is in communication with the lens 308, captures the images at the different focuses. Due to the objective lens 308, the camera 314 can capture alignment marks 206 and die marks 208 with widths less than 50 μm. The images are sent to the controller 122. An image processing algorithm executed by the controller 122 determines which image is in focus. In some embodiments, which can be combined with other embodiments described herein, autofocus data based on process history from the IPSs 110 is obtained from the IPSs 110. The autofocus data is utilized with the image processing algorithm to predict which image is in focus. In other embodiments, which can be combined with other embodiments described herein, the image processing algorithm is calibrated with the autofocus data.

The images of the alignment marks 206 are captured to ensure overlay alignment accuracy. The alignment marks 206 also define a metrology coordinate system of the substrate 120. The images of the die marks 208 are captured to analyze die shift and rotation of the dies 204.

At operation 404, positions of the alignment marks 206 and the die marks 208 are determined based on the images. The positons of the alignment marks 206 and the die marks 208 are determined from the in focus images. The position of the alignment marks 206 and the die marks 208 are determined relative to the metrology coordinate system. As such, the position of the alignment marks 206 and the die marks 208 on the metrology coordinate system are determined. In some embodiments, which can be combined with other embodiments described herein, the metrology coordinate system is calibrated with a lithography coordinate system. The lithography coordinate system is the coordinate system mapped on the substrate 120 relative to the IPSs 110 during subsequent patterning processes. By transferring the metrology coordinate system to the IPSs 110, subsequent patterning steps will be able to digitally correct any placement errors of the dies 204.

The actual positions of the alignment marks 206 and the die marks 208 are obtained. The actual position data is sent to the controller 122 for further processing. The actual positions of the alignment marks 206 and the die marks 208 are compared with a design file (e.g., GDS file). The design file includes design positions of the alignment marks 206 and the die marks 208. The difference between the design positions and actual positions are compared. Based on the difference, the controller 122 determines correction data. The correction data allows for compensation for the differences between the design positions and actual positions such that subsequent patterns will be aligned with the design file.

The correction data provides updated positions of connection points 210 between dies 204 to be formed in subsequent patterning operations. Further, the difference between the design positions and actual positions will allow for overlay alignment accuracy when patterning subsequent layers. The difference between the design positions and actual positions allows for digital correction printing to correct die placement errors. In-situ verification of process stability is also verifiable based on the difference between design positions and actual positions.

At operation 405, the digital lithography system 100 patterns the substrate 120 based on the correction data. The IPSs 110 pattern the substrate 120 according to the adjustments determined in operation 403 to better align with the design file. The controller 122 is provided updated instructions for patterning. As such, the overlayed layers are aligned and connection points 210 between dies 204 are located according to the design file.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The method disclosed herein includes one or more operations for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

In summation, embodiments of the present disclosure relate to a digital lithography system and method for alignment resolution with the digital lithography system. The digital lithography system includes a metrology system configured to improve overlay alignment for different layers of the lithography process. The metrology system allows for reduction in size of the alignment marks and die marks, while still allowing for obtaining correction data for digital die correction and overlay alignment. Additionally, the metrology tool improves process stability because the metrology tool can be combined with offline tools for statistical process control.

While the foregoing is directed to embodiments of the present invention, other and further embodiments of the invention may be devised without departing from the basic scope thereof, and the scope thereof is determined by the claims that follow.

1. A metrology system, comprising:
a microscope body;
a lens coupled to the microscope body;
a focusing stage disposed between the microscope body and the lens, wherein the focusing stage is configured to move the lens to adjust a focus of the lens;
a camera coupled to the microscope body;
a first LED, a second LED, and a third LED coupled to the microscope body, wherein the LEDs deliver light to the microscope body; and
an illuminator disposed below the lens.

2. The metrology system of claim 1, further comprising a controller, wherein the controller is configured to instruct the focusing stage to move the lens to adjust the focus, wherein the camera captures images at multiple focuses.

3. The metrology system of claim 1, wherein the focusing stage is coupled to a piezoelectric motor.

4. The metrology system of claim 1, wherein the first LED, the second LED, and the third LED are in communication with an illumination controller configured to provide different wavelengths of the first LED, the second LED, and the third LED to the microscope body.

5. The metrology system of claim 1, wherein the camera is configured to capture images of alignment marks and die marks with widths less than 50 μm.

6. A digital lithography system, comprising:
a slab;
a moveable stage disposable over the slab, the moveable stage configured to support a substrate;
a support coupled to the slab having an opening to allow the moveable stage to pass thereunder;
one or more image projection systems (IPSs) coupled to the support; and
one or more metrology systems coupled to the support, wherein the one or more metrology systems each include:
a microscope body;
a lens coupled to the microscope body;
a focusing stage disposed between the microscope body and the lens,
wherein the focusing stage is configured to move the lens to adjust a focus of the lens;
a camera coupled to the microscope body;
a first LED, a second LED, and a third LED coupled to the microscope body, wherein the LEDs deliver light to the microscope body; and
an illuminator disposed below the lens.

7. The digital lithography system of claim 6, wherein the lens is an objective lens.

8. The digital lithography system of claim 7, wherein the first LED provides bright field light at a wavelength between about 470 nm to about 530 nm, the second LED provides bright field light at a wavelength between about 365 nm and about 590 nm, and the third LED provides bright field light at a wavelength between about 617 nm and about 850 nm.

9. The digital lithography system of claim 7, wherein the first LED, the second LED, and the third LED are in communication with an illumination controller configured to provide different wavelengths of the first LED, the second LED, and the third LED to the microscope body; and
the focusing stage is coupled to a piezoelectric motor.

10. The digital lithography system of claim 7, the first LED, the second LED, and the third LED are in communication with an illumination controller configured to provide different wavelengths of the first LED, the second LED, and the third LED to the microscope body.

11. The digital lithography system of claim 6, wherein the focusing stage is coupled to a piezoelectric motor.

12. The digital lithography system of claim 6, wherein the camera is configured to capture images of alignment marks and die marks with widths less than 50 μm.

13. The digital lithography system of claim 6, wherein two or more image projection systems are (IPSs) coupled to the support and two or more metrology systems are coupled to the support.

14. The digital lithography system of claim 6, wherein a number of IPSs is equal to a number of the metrology systems.

15. The digital lithography system of claim 6, further comprising a controller, wherein the controller is configured to instruct the focusing stage to move the lens to adjust the focus, wherein the camera captures images at multiple focuses.

16. A method of mark measurements on a substrate;
moving a lens vertically to adjust a focus of the lens on a substrate;
providing illumination to the substrate via one or more LEDs and an illuminator;
capturing images of alignment marks on the substrate or die marks on dies of the substrate positioned on a digital lithography system, wherein the images are captured at different focuses by moving the lens vertically, wherein the alignment marks and the die marks each have a width less than 50 um, wherein the images of the alignment marks or the die marks are captured with a microscope body coupled to the lens;
determining a position of the alignment marks and the die marks;
comparing the position of the alignment marks and the die marks with a design file to obtain correction data; and
patterning subsequent layers onto the substrate with reference to the correction data, wherein the correction data improves overlay alignment accuracy of the subsequent layers and corrects die placement errors on the substrate.

17. The method of claim 16, wherein the images are captured at different focuses of the lens.

18. The method of claim 17, wherein the lens is moved vertically relative to the substrate to adjust the focus.

19. The method of claim 16, wherein the alignment marks are disposed on the substrate and define a metrology coordinate system.

20. The method of claim 16, wherein the images of the die marks are captured to analyze die shift and rotation of the dies.
